(19) United States
(12) Patent Application Publication
(10) Pub. No.: US 2026/0150695 A1
(43) Pub. Date: May 28, 2026

(54) SEMICONDUCTOR PACKAGE WITH MESH PATTERN AND MANUFACTURING METHOD THEREOF

(71) Applicant: SAMSUNG ELECTRONICS CO., LTD., Suwon-si (KR)

(72) Inventors: Keunyoung LEE, Suwon-si (KR); Minjong WANG, Suwon-si (KR); Eunhye LEE, Suwon-si (KR)

(73) Assignee: SAMSUNG ELECTRONICS CO., LTD., Suwon-si (KR)

(21) Appl. No.: 19/222,284

(22) Filed: May 29, 2025

(30) Foreign Application Priority Data
Nov. 27, 2024 (KR) 10-2024-0171867

(51) Int. Cl. H01L 23/552; H01L 23/00; H01L 23/31; H01L 23/498; H01L 23/538; H01L 25/18; H10B 80/00; H10D 80/30

(52) U.S. Cl. CPC H10W 42/20; H10B 80/00; H10D 80/30; H10W 70/611; H10W 70/65; H10W 74/111; H10W 90/00; H10W 42/271; H10W 72/865; H10W 72/884; H10W 74/15; H10W 90/20; H10W 90/24; H10W 90/701; H10W 90/724; H10W 90/732; H10W 90/734; H10W 90/752; H10W 90/754

(57) ABSTRACT

A semiconductor package includes a substrate including signal patterns and ground patterns, an upper protective layer on an upper surface of the substrate and including a first opening exposing a first portion of each of the signal patterns and the ground patterns and a second opening exposing a second portion of the ground patterns, a first semiconductor chip on the upper protective layer and coupled with the signal patterns and the ground patterns, a second semiconductor chips around the first semiconductor chip and coupled with the signal patterns and the ground patterns, a mesh pattern layer on the upper protective layer, overlapping respective portions of the signal patterns and the ground patterns, and coupled with the ground patterns, a molded layer covering the first semiconductor chip, the second semiconductor chips, and the mesh pattern layer, and external connection bumps below the substrate.

### CROSS-REFERENCE TO RELATED APPLICATIONS

This application claims priority under 35 U.S.C. § 119 to Korean Patent Application No. 10-2024-0171867, filed on Nov. 27, 2024, in the Korean Intellectual Property Office, the disclosure of which is incorporated by reference herein in its entirety.

### BACKGROUND

### 1. Field

The present disclosure relates generally to semiconductor packages, and more particularly, to a semiconductor package with a mesh pattern and a manufacturing method thereof.

### 2. Description of Related Art

At least in part as a response to demands for relatively high performance in electronic devices, high-speed signal transmission may be performed between components included by the electronic devices. The high-speed signal transmissions may be susceptible to interference from electromagnetic waves. Efforts to block electromagnetic waves that may be generated when high-frequency signals are transmitted may include forming an electromagnetic shielding layer on an outer surface of a semiconductor package. However, the shielding of electromagnetic interference (EMI) on the outer surface of the semiconductor packages may not prevent EMI of components inside the semiconductor package. Thus, there exists a need for further improvements in semiconductor packaging technology, as the need for high-speed signal transmission may be constrained by EMI inside the semiconductor packages. Improvements are presented herein. These improvements may also be applicable to other semiconductor technologies.

### SUMMARY

One or more example embodiments of the present disclosure provide a semiconductor package in which internal electromagnetic interference is prevented and/or reduced, when compared to related semiconductor packages.

According to an aspect of the present disclosure, a semiconductor package includes a substrate including a plurality of signal patterns and a plurality of ground patterns, an upper protective layer on an upper surface of the substrate and including a first opening exposing at least a first portion of each pattern of the plurality of signal patterns and the plurality of ground patterns and a second opening exposing at least a second portion of the plurality of ground patterns, a first semiconductor chip on the upper protective layer and coupled with the plurality of signal patterns and the plurality of ground patterns through the first opening, a plurality of second semiconductor chips around the first semiconductor chip and coupled with the plurality of signal patterns and the plurality of ground patterns through the first opening, a mesh pattern layer on the upper protective layer, at least partially overlapping respective portions of the plurality of signal patterns and the plurality of ground patterns, and coupled with the plurality of ground patterns through the second opening, a molded layer at least partially covering the first semiconductor chip, the plurality of second semiconductor chips, and the mesh pattern layer, and a plurality of external connection bumps below the substrate.

According to an aspect of the present disclosure, a semiconductor package includes a substrate including a signal pattern and a ground pattern adjacent to a side surface of the signal pattern and a lower surface of the signal pattern, an upper protective layer at least partially covering respective portions of the signal pattern and the ground pattern, a controller and one or more memory chips on the upper protective layer and coupled with the signal pattern and the ground pattern, a mesh pattern layer on the upper protective layer adjacent to an upper surface of the signal pattern and including a plurality of holes at least partially overlapping the signal pattern, a molded layer at least partially covering the controller, the one or more memory chips, and the mesh pattern layer, and an electromagnetic shielding layer at least partially covering respective surfaces of the substrate and the molded layer. The mesh pattern layer is coupled with the electromagnetic shielding layer through the ground pattern.

According to an aspect of the present disclosure, a semiconductor package includes a substrate including a first bonding pad, a second bonding pad, and a first signal pattern coupling the first bonding pad with the second bonding pad, an upper protective layer on the substrate and at least partially covering the first signal pattern, a first semiconductor chip on the upper protective layer and including a plurality of first chip pads coupled with the first bonding pad, a plurality of second semiconductor chips on the upper protective layer and including a plurality of second chip pads coupled with the second bonding pad, and a first mesh pattern layer on the upper protective layer between the first bonding pad and the second bonding pad and including a first plurality of holes at least partially overlapping the first signal pattern.

According to an aspect of the present disclosure, a method of manufacturing a semiconductor package includes preparing a preliminary substrate, forming a protective layer on the preliminary substrate, forming a first opening and a second opening at least partially penetrating an upper protective layer of the protective layer, and forming a mesh pattern layer on the upper protective layer. The preliminary substrate includes a signal pattern, a ground pattern, and an insulating layer separating the signal pattern and the ground pattern. The ground pattern is laterally adjacent and downwardly adjacent to the signal pattern. The upper protective layer at least partially covers the signal pattern. The signal pattern is upwardly adjacent to the mesh pattern layer.

The forming of the first opening may include exposing at least a portion of at least one of the ground pattern or the signal pattern.

The forming of the second opening may include exposing at least a portion of the ground pattern.

The forming of the mesh pattern layer may include directly printing an electromagnetic interference shielding material on the upper protective layer.

The forming of the mesh pattern layer may include forming a plurality of first lines and a plurality of second lines intersecting the plurality of first lines. The mesh pattern layer includes a plurality of mesh holes defined by the plurality of first lines and the plurality of second lines.

The method of manufacturing the semiconductor package may further include determining a maximum width of each mesh hole of the plurality of mesh holes based on a wavelength of an electromagnetic wave generated from the signal pattern.

The forming of the mesh pattern layer may include connecting the mesh pattern layer to the ground pattern by forming a connecting via within the second opening.

The method of manufacturing the semiconductor package may further include mounting, on the preliminary substrate, a first semiconductor chip and a plurality of second semiconductor chips, connecting the first semiconductor chip to an interconnection layer of the preliminary substrate through at least one bonding bump, forming an underfill at least partially surrounding the at least one bonding bump, and connecting the plurality of second semiconductor chips to the interconnection layer through at least one bonding wire.

The method of manufacturing the semiconductor package may further include forming a molded layer on a first side of the preliminary substrate, the first semiconductor chip, and the plurality of second semiconductor chips, forming external connection bumps on a second side of the preliminary substrate opposite to the first side, and forming an electromagnetic shielding layer at least partially covering the preliminary substrate and the molded layer. The electromagnetic shielding layer may be coupled to the ground pattern.

Additional aspects may be set forth in part in the description which follows and, in part, may be apparent from the description, and/or may be learned by practice of the presented embodiments.

### BRIEF DESCRIPTION OF DRAWINGS

The above and other aspects, features, and advantages of certain embodiments of the present disclosure may be more apparent from the following description, taken in conjunction with the accompanying drawings, in which:

FIG. 1A is a plan view of a semiconductor package, according to an example embodiment;

FIG. 1B is a cross-sectional view taken along line I-I′ of FIG. 1A, according to an example embodiment;

FIG. 1C is a cross-sectional view taken along line II-II′ of FIG. 1A, according to an example embodiment;

FIG. 2 is a plan view of a semiconductor package, according to an example embodiment;

FIG. 3A is a plan view of a semiconductor package, according to an example embodiment;

FIG. 3B is a cross-sectional view taken along line III-III′ of FIG. 1A, according to an example embodiment;

FIG. 4A is a plan view of a semiconductor package, according to an example embodiment;

FIG. 4B is a cross-sectional view taken along line IV-IV′ of FIG. 4A, according to an example embodiment;

FIG. 5 is a plan view of a semiconductor package, according to an example embodiment; and

FIGS. 6A to 6D are drawings illustrating a method of manufacturing a semiconductor package, according to an example embodiment.

### DETAILED DESCRIPTION

The following description with reference to the accompanying drawings is provided to assist in a comprehensive understanding of embodiments of the present disclosure defined by the claims and their equivalents. Various specific details are included to assist in understanding, but these details are considered to be exemplary only. Therefore, those of ordinary skill in the art may recognize that various changes and modifications of the embodiments described herein may be made without departing from the scope and spirit of the disclosure. In addition, descriptions of well-known functions and structures are omitted for clarity and conciseness.

With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wired), wirelessly, or via a third element.

Unless otherwise specified, as used herein, terms such as “upper portion,” “upper surface,” “lower portion,” “lower surface,” “side,” “side surface,” or the like may be based on the drawings, and in actuality, may vary depending on the direction in which the components are disposed.

Additionally, ordinal numbers such as “first,” “second,” “third,” or the like may be used as labels for specific elements, steps, directions, or the like to distinguish various elements, steps, directions, or the like from each other. Terms that are not described using “first,” “second,” or the like in the specification may still be referred to as “first” or “second” in the claims. Additionally, terms (e.g., “first” in a specific claim) referenced by a specific ordinal number may be described elsewhere with a different ordinal number (e.g., “second” in the specification or another claim). That is, the terms “first”, “second”, “third”, or the like may be used to distinguish components from each other and may not limit the present disclosure. For example, the terms “first”, “second”, “third”, or the like may not necessarily involve an order or a numerical meaning of any form.

It is to be understood that when an element or layer is referred to as being “over,” “above,” “on,” “below,” “under,” “beneath,” “connected to” or “coupled to” another element or layer, it may be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

As used herein, when an element or layer is referred to as “covering”, “overlapping”, or “surrounding” another element or layer, the element or layer may cover at least a portion of the other element or layer, where the portion may include a fraction of the other element or may include an entirety of the other element. Similarly, when an element or layer is referred to as “penetrating” another element or layer, the element or layer may penetrate at least a portion of the other element or layer, where the portion may include a fraction of the other element or may include an entire dimension (e.g., length, width, depth) of the other element.

Reference throughout the present disclosure to “one embodiment,” “an embodiment,” “an example embodiment,” or similar language may indicate that a particular feature, structure, or characteristic described in connection with the indicated embodiment is included in at least one embodiment of the present solution. Thus, the phrases “in one embodiment”, “in an embodiment,” “in an example embodiment,” and similar language throughout this disclosure may, but do not necessarily, all refer to the same embodiment. The embodiments described herein are example embodiments, and thus, the disclosure is not limited thereto and may be realized in various other forms.

In the present disclosure, the articles “a” and “an” are intended to include one or more items, and may be used interchangeably with “one or more.” Where only one item is intended, the term “one” or similar language is used. For example, the term “a package” may refer to either a single package or multiple packages. When a package is described as carrying out an operation and the package is referred to perform an additional operation, the multiple operations may be executed by either a single package or any one or a combination of multiple packages.

Hereinafter, various embodiments of the present disclosure are described with reference to the accompanying drawings.

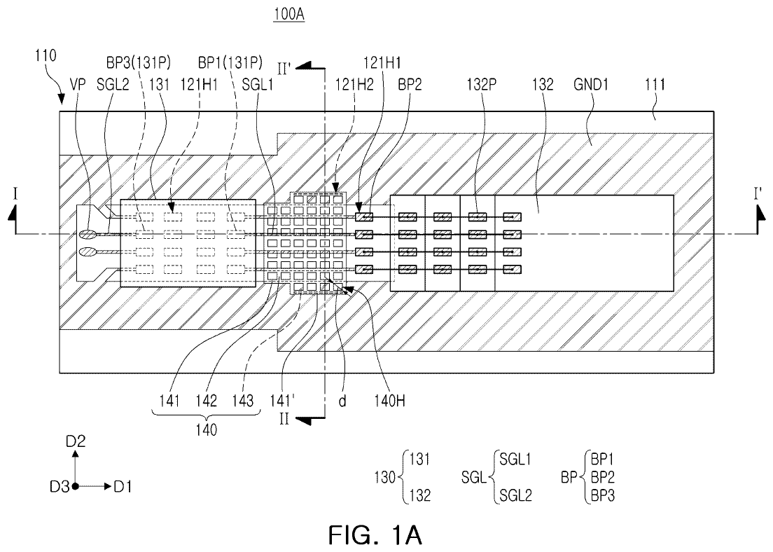

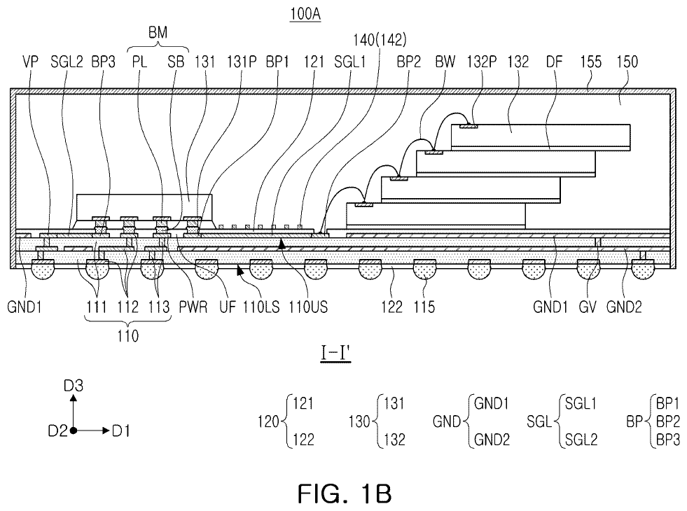

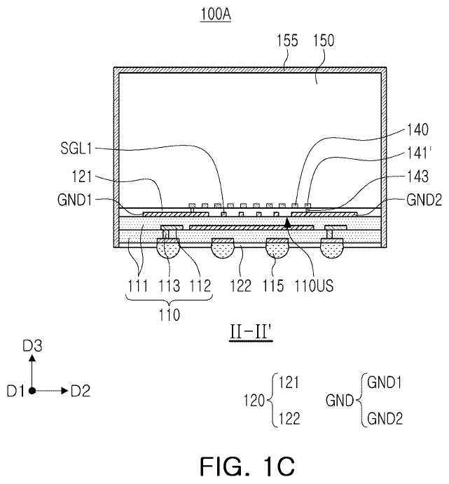

FIG. 1A is a plan view of a semiconductor package 100A, according to an example embodiment. FIG. 1B is a cross-sectional view taken along line I-I′ of FIG. 1A, according to an example embodiment. FIG. 1C is a cross-sectional view taken along line II-II′ of FIG. 1A, according to an example embodiment. In FIG. 1A, the upper protective layer 121, the molded layer 150, and the electromagnetic shielding layer 155 illustrated in FIGS. 1B and 1C may be omitted for the sake of simplicity.

Referring to FIGS. 1A, 1B, and 1C, the semiconductor package 100A of an example embodiment may include a substrate 110, a protective layer 120, a plurality of semiconductor chips 130, and a mesh pattern layer 140. According to an example embodiment, the semiconductor package 100A may further include a molded layer 150 and/or an electromagnetic shielding layer 155.

The substrate 110 may be and/or may include a support substrate on which a plurality of semiconductor chips 130 may be mounted. Alternatively or additionally, the substrate 110 may be and/or may include a semiconductor package substrate including, but not being limited to, at least one of a printed circuit board (PCB), a ceramic substrate, a glass substrate, a tape interconnection substrate, or the like. For example, the substrate 110 may be a double-sided printed circuit board (double-sided PCB) and/or a multi-layer printed circuit board (multi-layer PCB). The substrate 110 may include an insulating layer 111, an interconnection layer 112, and an interconnection via 113.

The insulating layer 111 may include an insulating material that may electrically and/or physically protect the interconnection layer 112. For example, the insulating layer 111 may include, but not be limited to, a thermosetting resin (e.g., an epoxy resin), a thermoplastic resin (e.g., a polyimide), a prepreg mixed with these resins, inorganic fillers, and/or glass fibers (e.g., glass cloth, glass fabric), a composite resin (e.g., Ajinomoto build-up film (ABF), frame retardant 4(FR4)), a photosensitive resin (e.g., photo-imageable dielectric (PID)), or the like. The insulating layer 111 may include a plurality of insulating layers 111 laminated in a vertical direction D3. In some embodiments, a boundary between the insulating layers 111 may be unclear based on the process used to manufacture the insulating layers 111. In addition, for convenience of explanation, only two (2) insulating layers 111 may be illustrated in the drawings. However, embodiments of the present disclosure are not limited thereto.

For example, in some embodiments, the insulating layer 111 may include a core insulating layer to improve the rigidity of the substrate 110. The core insulating layer may be formed using, for example, a copper clad laminate (CCL), an unclad copper clad laminate (unclad CCL), a glass substrate, a ceramic substrate, or the like.

The interconnection layer 112 may extend in the horizontal direction D1 and D2 within the insulating layer 111. The interconnection layer 112 may include, but not be limited to, a metal material including, for example, copper (Cu), aluminum (Al), silver (Ag), tin (Sn), gold (Au), nickel (Ni), lead (Pb), titanium (Ti), or alloys thereof. However, embodiments of the present disclosure are not limited thereto. The interconnection layer 112 may electrically connect a plurality of semiconductor chips 130 and external connection bumps 115.

The external connection bumps 115 may be disposed under the substrate 110. The external connection bumps 115 may be electrically connected to an external device (e.g., a processor) through a module substrate, a system board, or the like. The external connection bumps 115 may include, for example, tin (Sn) or an alloy including tin (Sn) (e.g., Sn—Ag—Cu). However, embodiments of the present disclosure are not limited thereto.

The interconnection layer 112 may include a plurality of interconnection layers 112 arranged in a vertical direction D3 within the insulating layer 111. The plurality of interconnection layers 112 may be electrically connected to each other through interconnection vias 113. The number of layers of the interconnection layer 112 may be determined, according to the number of layers of the insulating layer 111, and may include more or fewer layers than those illustrated in the drawing.

The interconnection layer 112 may include a ground pattern GND, a power pattern PWR, and a signal pattern SGL. The ground pattern GND and the power pattern PWR may provide a path for applying a power voltage and a ground voltage to a plurality of semiconductor chips 130. The signal pattern SGL may provide a transmission path for a command signal, an address signal, and/or a data signal between an external device and/or the plurality of semiconductor chips 130. The external device communicating with the first semiconductor chip 131 may include, for example, a central processing unit (CPU), a graphic processing unit (GPU), or an application processor (AP). However, embodiments of the present disclosure are not limited thereto. The substrate 110 may be designed to minimize loss and interference of a high-frequency signal transmitted through the signal pattern SGL. For example, the dielectric constant of the insulating layer 111, the distance between the ground pattern GND and the signal pattern SGL, the line width and thickness of the signal pattern SGL, or the like may be determined in consideration of the loss and interference of the high-frequency signal and/or other design constraints.

The interconnection via 113 extends in a vertical direction D3 within the insulating layer 111 and may be connected to the interconnection layer 112. The interconnection via 113 may be electrically connected to a bonding pad portion (or bonding pad) BP and a via pad portion (or via pad) VP of the interconnection layer 112. The interconnection via 113 may include, but not be limited to, a metal material, for example, copper (Cu), aluminum (Al), silver (Ag), tin (Sn), gold (Au), nickel (Ni), lead (Pb), titanium (Ti), or alloys thereof. However, embodiments of the present disclosure are not limited thereto. The interconnection via 113 may have a filled via shape in which a metal material may be filled inside the via hole and/or the interconnection via 113 may have a conformal via shape in which a metal material may be formed along the inner wall of the via hole.

In an example embodiment, the signal pattern SGL may be a microstrip transmission line for performing relatively high-speed signal transmission between an external device and/or a plurality of semiconductor chips 130. The signal pattern SGL may be adjacent to a ground pattern GND laterally and downwardly, and the signal pattern SGL and the ground pattern GND may be separated by an insulating layer 111. That is, the signal pattern SGL may be adjacent to a mesh pattern layer 140 upwardly. Accordingly, a propagation path of an electromagnetic wave generated when a high-frequency signal is transmitted through the signal pattern SGL may be blocked, and electromagnetic interference generated inside the package may be prevented and/or reduced, when compared to a related semiconductor package.

For example, the ground patterns GND may include a first ground pattern GND1 adjacent to a side surface of the signal patterns SGL, and a second ground pattern GND2 adjacent to a lower surface of the signal patterns SNL. The signal patterns SGL may overlap with the first ground pattern GND1 in the horizontal direction D1 and D2 and may overlap with the mesh pattern layer 140 and the second ground pattern GND2 in the vertical direction D3. The first ground pattern GND1 and the second ground pattern GND2 may be connected through a ground via GV.

The protective layer 120 may be disposed on both sides of the substrate 110. The protective layer 120 may cover the interconnection layer 112 exposed from the upper and lower sides of the substrate 110 and protect the interconnection layer from external physical and chemical damage. The protective layer 120 may be formed using, for example, a photo solder resist (PSR). However, embodiments of the present disclosure are not limited thereto.

The protective layer 120 may include an upper protective layer 121 covering an upper surface 110US of the substrate 110 and a lower protective layer 122 covering a lower surface 110LS of the substrate 110. The upper protective layer 121 may cover at least a portion of each of a ground pattern GND, a power pattern PWR, and a signal pattern SGL extending along the upper surface 110US of the substrate 110. The upper protective layer 121 may include openings 121H1 and 121H2 exposing at least a portion of each of the ground pattern GND, the power pattern PWR, and the signal pattern SGL. The upper protective layer 121 may include a first opening 121H1 exposing at least a portion (e.g., a bonding pad portion) of each of the ground pattern GND, the power pattern PWR, and the signal pattern SGL, and a second opening 121H2 exposing at least a portion of the ground pattern GND. The lower protective layer 122 may expose a pad portion of a lowermost interconnection layer 112 to which external connection bumps 115 are attached. In some embodiments, the lower protective layer 122 may be omitted.

A plurality of semiconductor chips 130 may be disposed on the upper protective layer 121. The plurality of semiconductor chips 130 may include a first semiconductor chip 131 and a plurality of second semiconductor chips 132. The first semiconductor chip 131 and the plurality of second semiconductor chips 132 may be disposed side by side on the substrate 110.

A first semiconductor chip 131 and a plurality of second semiconductor chips 132 may be connected to a ground pattern GND, a power pattern PWR, and a signal pattern SGL exposed through a first opening 121H1 of an upper protective layer 121. A first chip pad 131P of the first semiconductor chip 131 may be connected to a bonding pad portion BP of an interconnection layer 112 through a bonding bump BM.

The bonding bump BM may include a pillar portion PL and a solder portion SB. The pillar portion PL may include copper (Cu) or an alloy of copper (Cu), and the solder portion SB may include a low-melting-point metal, for example, tin (Sn) or an alloy including tin (Sn) (e.g., Sn—Ag—Cu). However, embodiments of the present disclosure are not limited thereto.

The underfill UF may surround the bonding bump BM between the first semiconductor chip 131 and the substrate 110. According to an example embodiment, the first semiconductor chip 131 may be wire bonded on the substrate 110. The second chip pads 132P of the plurality of second semiconductor chips 132 may be connected to the bonding pad portions BP of the interconnection layer 112 through bonding wires BW. The plurality of second semiconductor chips 132 may be adhered on the substrate 110 by an attachment film DF. The attachment film DF may be, but is not limited to, a die attach film (DAF). For convenience of explanation, only the connection relationship between some chip pads 131P and 132P and a signal pattern SGL and a ground pattern GND is illustrated in FIG. 1A. It may be understood that a greater number of first and second chip pads 131P and 132P than those illustrated in the drawing may be connected to the signal pattern SGL, the ground pattern GND, and the power pattern PWR

The first semiconductor chip 131 may be and/or may include a controller configured to determine the data processing order of a plurality of second semiconductor chips 132 and/or prevent errors and/or bad sectors. For example, the first semiconductor chip 131 may generate a command signal, an address signal, a data signal, or the like. The plurality of second semiconductor chips 132 may be and/or may include memory chips configured to store data received from the first semiconductor chip 131 and/or re-output stored data. The plurality of second semiconductor chips 132 may include, but not be limited to, nonvolatile memory chips (e.g., flash memory, phase-change random access memory (PRAM), magneto-resistive random access memory (MRAM), ferroelectric random access memory (FeRAM), resistive random access memory (RRAM), or the like) and/or volatile memory chips (e.g., dynamic random access memory (DRAM), static random access memory (SRAM), or the like).

The mesh pattern layer 140 may be disposed on the upper protective layer 121 covering the signal pattern SGL. The mesh pattern layer 140 may be positioned adjacent to the upper surface of the signal pattern SGL. The mesh pattern layer 140 may include at least one of iron (Fe), nickel (Ni), gold (Au), silver (Ag), copper (Cu), or alloys thereof. However, embodiments of the present disclosure are not limited thereto. The mesh pattern layer 140 may include first lines 141 and second lines 142 intersecting the first lines 141. For example, the first lines 141 may extend in a first direction D1, and the second lines 142 may extend in a second direction D2 perpendicular to the first direction D1. The mesh pattern layer 140 may include mesh holes 140H defined by the first lines 141 and the second lines 142.

The mesh holes 140H may overlap the signal pattern SGL in the vertical direction D3. Although, the mesh holes 140H shown in FIG. 1A may be illustrated as rectangles, the present disclosure is not limited in this regard. For example, the mesh holes 140H may have a polygonal shape such as, but not limited to, a square, a diamond, or the like, and/or a circular plane shape. The mesh holes 140H may be formed to a size capable of blocking the propagation of electromagnetic waves generated from the signal pattern SGL. In an embodiment, the diameter and/or maximum width d of each of the mesh holes 140H may be about 5% or less of the wavelength of the electromagnetic waves generated when transmitting a high-frequency signal. For example, the diameter and/or maximum width d may have a range of about 2% to about 5%. In this example, the high-frequency signal may be a signal having a frequency ranging from about 1 GHz to about 48 GHz. However, embodiments of the present disclosure are not limited thereto. If the maximum width d of each of the mesh holes 140H exceeds about 5% of the electromagnetic wave wavelength, the electromagnetic wave blocking effect may be reduced. If the maximum width d of each of the mesh holes 140H is less than about 2% of the electromagnetic wave wavelength, the efficiency of the forming process of the mesh pattern layer 140 may be reduced.

The mesh pattern layer 140 may be connected to the ground pattern GND on at least one side. The mesh pattern layer 140 may overlap both the signal pattern SGL and the ground pattern GND, and may be connected to the ground pattern GND through a connecting via 143. For example, at least one line 141′ of the first line 141 and the second line 142 of the mesh pattern layer 140 may overlap the second opening 121H2 of the upper protective layer 121. A connecting via 143 may be disposed in the second opening 121H2 of the upper protective layer 121 to connect at least one of the first line 141 and the second line 142 to a ground pattern GND. The second opening 121H2 may have a trench shape extending along the longitudinal direction of at least one of the corresponding first line 141 and the second line 142.

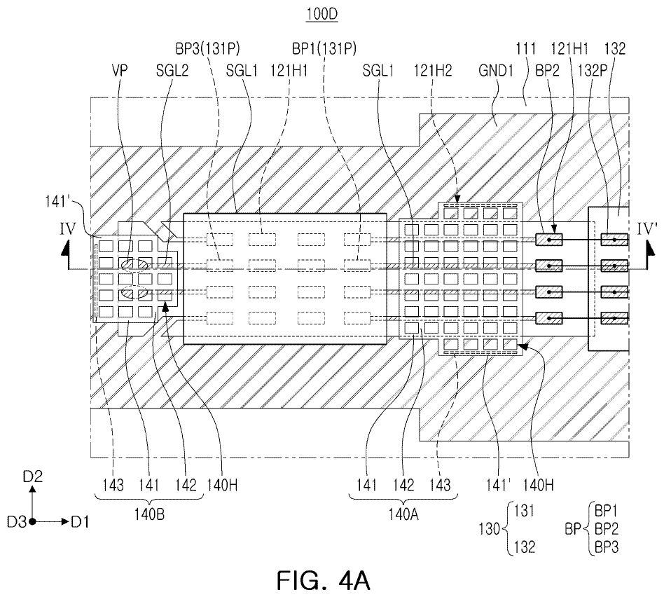

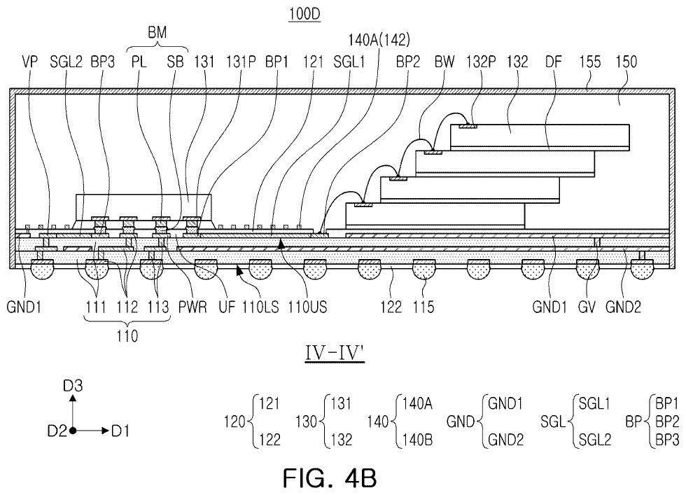

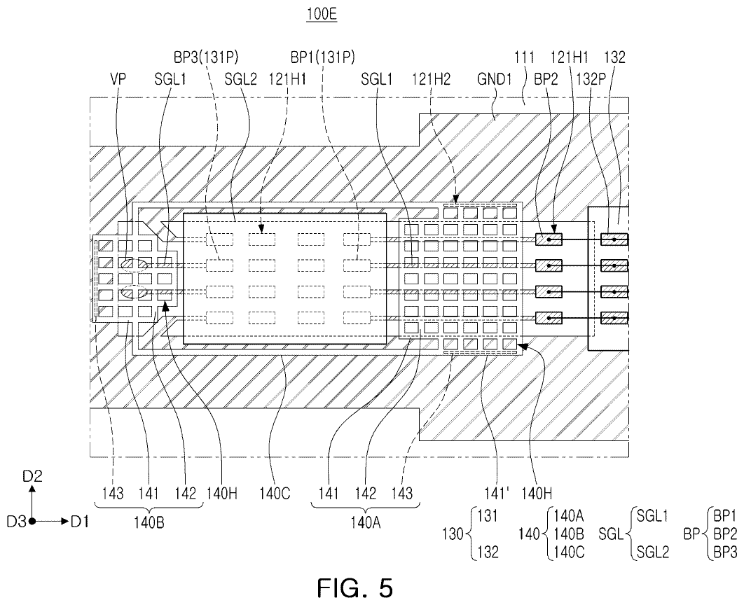

In an example embodiment, the substrate 110 may include a first signal pattern SGL1 and a second signal pattern SGL2, and the mesh pattern layer 140 may overlap at least one of the first signal pattern SGL1 and the second signal pattern SGL2. According to an example embodiment, the mesh pattern layer 140 may overlap both the first signal pattern SGL1 and the second signal pattern SGL2 (as shown in FIGS. 4A to 5). The first signal pattern SGL1 may provide a signal transmission path between the first semiconductor chip 131 and the second semiconductor chips 132. The first signal pattern SGL1 may extend on the upper surface 110US of the substrate 110 to connect the first bonding pad BP1 and the second bonding pad BP2. The first bonding pad BP1 may be connected to the first semiconductor chip 131, and the second bonding pad BP2 may be connected to the second semiconductor chips 132. The second signal pattern SGL2 may provide a signal transmission path between the first semiconductor chip 131 and the external connection bump 115. The second signal pattern SGL2 may extend on the upper surface 110US of the substrate 110 to connect the third bonding pad BP3 and the via pad VP. The third bonding pad BP3 may be connected to the first semiconductor chip 131, and the via pad VP may be connected to the external connection bump 115 through the interconnection layer 112 and the via 113.

The molded layer 150 may cover a plurality of semiconductor chips 130 and the mesh pattern layer 140. The molded layer 150 may include, for example, an insulating resin such as epoxy molding compound (EMC). However, embodiments of the present disclosure are not limited thereto. The electromagnetic shielding layer 155 may cover at least a portion of each of the substrate 110 and the molded layer 150. The electromagnetic shielding layer 155 may extend along outer surfaces of the substrate 110 and the molded layer 150. The electromagnetic shielding layer 155 may be connected to a ground pattern GND on at least one side of the substrate 110. The electromagnetic shielding layer 155 may include a conductive material for EMI shielding, such as, but not limited to, iron (Fe), nickel (Ni), gold (Au), silver (Ag), copper (Cu), or alloys thereof. The electromagnetic shielding layer 155 may be a multilayer thin film of two (2) or more layers.

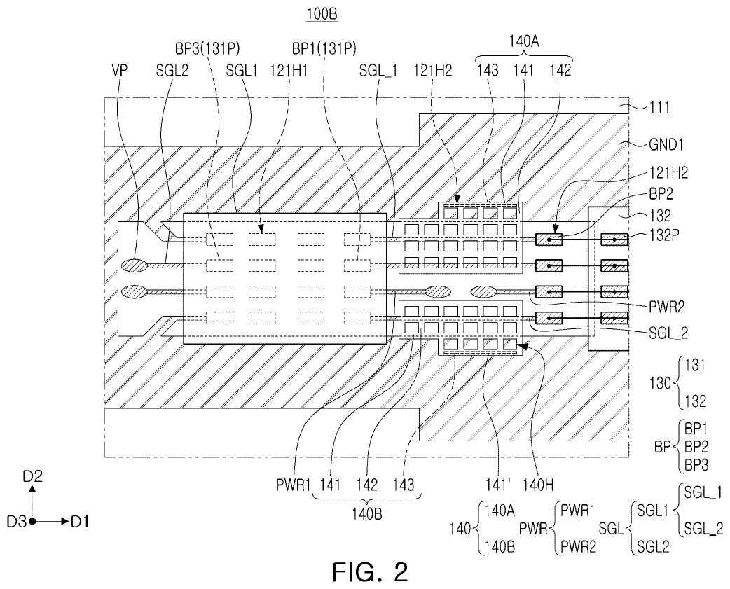

FIG. 2 is a plan view of a semiconductor package 100B, according to an example embodiment. The semiconductor package 100B may include and/or may be similar in many respects to the semiconductor package 100A described above with reference to FIGS. 1A to 1C, and may include additional features not mentioned above. Consequently, repeated descriptions of the semiconductor package 100B described above with reference to FIGS. 1A to 1C may be omitted for the sake of brevity. For example, FIG. 2 may only illustrate components corresponding to a portion of FIG. 1A.

Referring to FIG. 2, the semiconductor package 100B, of an example embodiment, may have the same or similar features as those described with reference to FIGS. 1A to 1C, except that the semiconductor package 100B includes a mesh pattern layer 140 divided into two (2) or more layers. That is, the mesh pattern layer 140 may be divided and disposed on transmission paths of a high-frequency signal, respectively. For example, at least some of the signal patterns SGL may be separated into a first group SGL_1 and a second group SGL_2 with a power pattern PWR therebetween. As another example, the mesh pattern layer 140 may include a first mesh pattern layer 140A overlapping with the signal pattern SGL_1 of the first group and a second mesh pattern layer 140B overlapping with the signal pattern SGL_2 of the second group. The first mesh pattern layer 140A and the second mesh pattern layer 140B may be spaced apart from each other. In such an example, the first mesh pattern layer 140A and the second mesh pattern layer 140B may each be connected to the ground pattern GND. In some embodiments, the first mesh pattern layer 140A and the second mesh pattern layer 140B may be connected to each other, and only one thereof may be connected to the ground pattern GND.

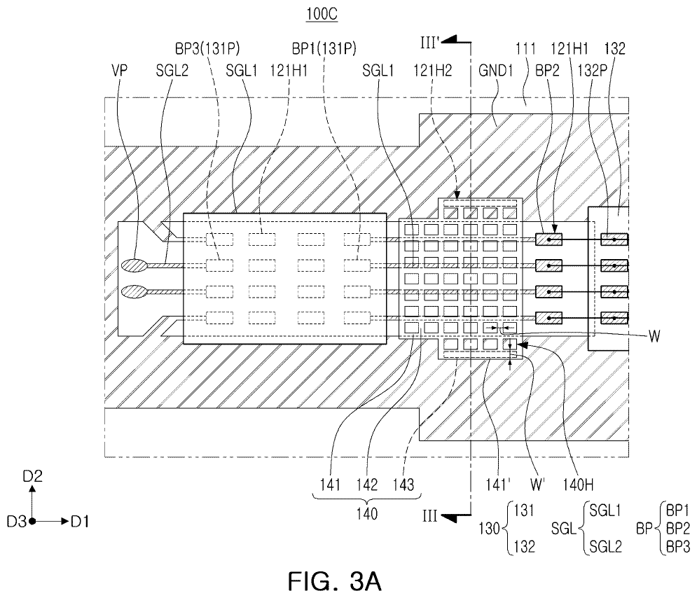

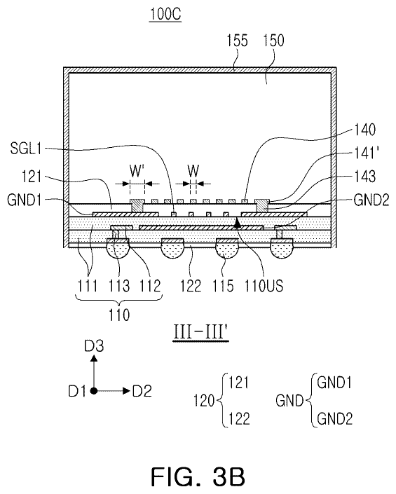

FIG. 3A is a plan view of a semiconductor package 100C, according to an example embodiment. FIG. 3B is a cross-sectional view taken along line III-III′ of FIG. 1A, according to an example embodiment. The semiconductor package 100C may include and/or may be similar in many respects to the semiconductor packages 100A and 100B described above with reference to FIGS. 1A to 2, and may include additional features not mentioned above. Consequently, repeated descriptions of the semiconductor package 100C described above with reference to FIGS. 1A to 2 may be omitted for the sake of brevity. For example, FIGS. 3A and 3B may illustrate only components corresponding to a portion of FIG. 1A.

Referring to FIGS. 3A and 3B, the semiconductor package 100C, of an example embodiment, may have substantially similar and/or the same features as those described with reference to FIGS. 1A to 2, except that at least a portion of the mesh pattern layer 140 may be formed as a wide line. The mesh pattern layer 140 may include first lines 141 extending in a first direction D1 and second lines 142 extending in a second direction D2. At least one line 141′ (hereinafter, referred to as a ground line) of the first lines 141 and the second lines 142 may be connected to a ground pattern GND through a second opening 121H2. In an example embodiment, the line width W′ of the ground line 141′ may be larger than the line widths W of the remaining first and second lines 141 and 142. The second opening 121H2 may be formed with a wide width corresponding to the line width W′ of the ground line 141′. Accordingly, connection reliability of the connecting via 143 and the ground pattern GND may be improved, when compared to related semiconductor packages.

FIG. 4A is a plan view of a semiconductor package 100D, according to an example embodiment. FIG. 4B is a cross-sectional view taken along line IV-IV′ of FIG. 4A, according to an example embodiment. The semiconductor package 100D may include and/or may be similar in many respects to the semiconductor packages 100A, 100B, and 100C described above with reference to FIGS. 1A to 3B, and may include additional features not mentioned above. Consequently, repeated descriptions of the semiconductor package 100D described above with reference to FIGS. 1A to 3B may be omitted for the sake of brevity. For example, FIGS. 4A and 4B may illustrated only components corresponding to a portion of FIG. 1A.

Referring to FIGS. 4A and 4B, the semiconductor package 100D, of an example embodiment, may have substantially similar and/or the same features as those described with reference to FIGS. 1A to 3B, except that the semiconductor package 100D may include a mesh pattern layer 140 divided into two (2) or more layers.

The substrate 110 may include a first signal pattern SGL1 and a second signal pattern SGL2. The first signal pattern SGL1 may extend on an upper surface 110US of the substrate 110 to connect a first bonding pad BP1 and a second bonding pad BP2. The first bonding pad BP1 may be connected to the first semiconductor chip 131, and the second bonding pad BP2 may be connected to the second semiconductor chips 132. The second signal pattern SGL2 may provide a signal transmission path between the first semiconductor chip 131 and the external connection bump 115. The second signal pattern SGL2 may extend on the upper surface 110US of the substrate 110 to connect the third bonding pad BP3 and the via pad VP. The third bonding pad BP3 may be connected to the first semiconductor chip 131, and the via pad VP may be connected to the external connection bump 115 through the interconnection layer 112 and the via 113.

The mesh pattern layer 140 may include a first mesh pattern layer 140A on a first signal pattern SGL1 and a second mesh pattern layer 140B on a second signal pattern SGL2. The first mesh pattern layer 140A may overlap the first signal pattern SGL1. The first mesh pattern layer 140A may include holes 140H overlapping the first signal pattern SGL1 between the first bonding pad BP1 and the second bonding pad BP2. The second mesh pattern layer 140B may overlap the second signal pattern SGL2. The second mesh pattern layer 140B may include holes 140H overlapping the second signal pattern SGL2 between the third bonding pad BP3 and the via pad VP. The first mesh pattern layer 140A and the second mesh pattern layer 140B may be connected to the ground pattern GND through a connecting via 143, respectively.

FIG. 5 is a plan view of a semiconductor package 100E, according to an example embodiment. The semiconductor package 100E may include and/or may be similar in many respects to the semiconductor packages 100A, 100B, 100C, and 100D described above with reference to FIGS. 1A to 4B, and may include additional features not mentioned above. Consequently, repeated descriptions of the semiconductor package 100E described above with reference to FIGS. 1A to 4B may be omitted for the sake of brevity. For example, FIG. 5 may illustrate only components corresponding to a portion of FIG. 1A.

Referring to FIG. 5, the semiconductor package 100E, of an example embodiment, may have substantially similar and/or the same features as those described with reference to FIGS. 1A to 4B, except that the mesh pattern layers 140 of the semiconductor package 100E divided on different signal patterns SGL may be connected to each other.

The mesh pattern layer 140 may include a first mesh pattern layer 140A, a second mesh pattern layer 140B, and a third mesh pattern layer 140C connecting the first mesh pattern layer 140A and the second mesh pattern layer 140B. The first mesh pattern layer 140A may overlap the first signal pattern SGL1. The first mesh pattern layer 140A may include holes 140H overlapping the first signal pattern SGL1 between the first bonding pad BP1 and the second bonding pad BP2. The second mesh pattern layer 140B may overlap the second signal pattern SGL2. The second mesh pattern layer 140B may include holes 140H overlapping the second signal pattern SGL2 between the third bonding pad BP3 and the via pad VP.

The third mesh pattern layer 140C may be connected to the first mesh pattern layer 140A and the second mesh pattern layer 140B, which may be spaced apart from each other. The third mesh pattern layer 140C may extend on the ground pattern GND to electrically connect the first mesh pattern layer 140A and the second mesh pattern layer 140B. In some embodiments, the first mesh pattern layer 140A and the second mesh pattern layer 140B may be connected to a ground pattern GND through a third mesh pattern layer 140C.

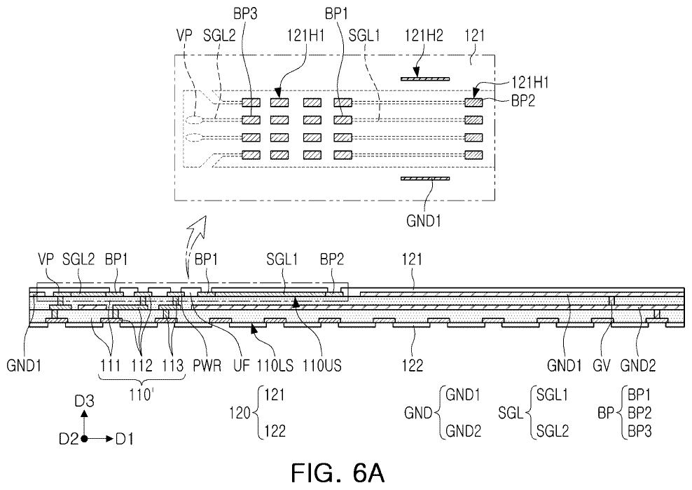

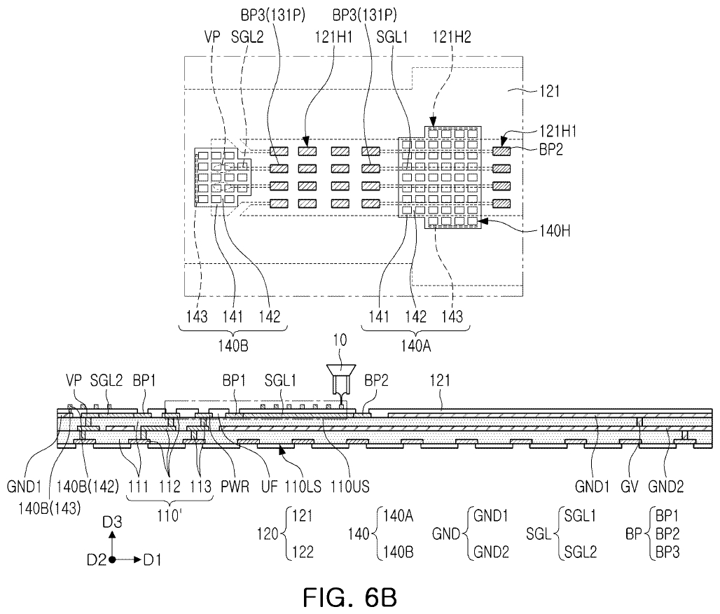

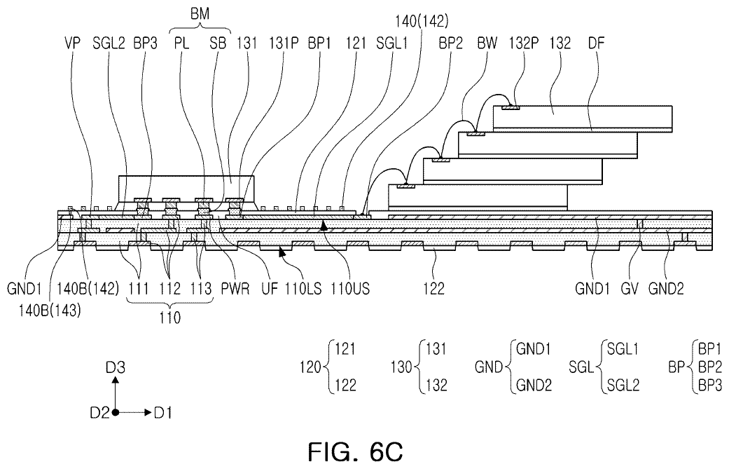

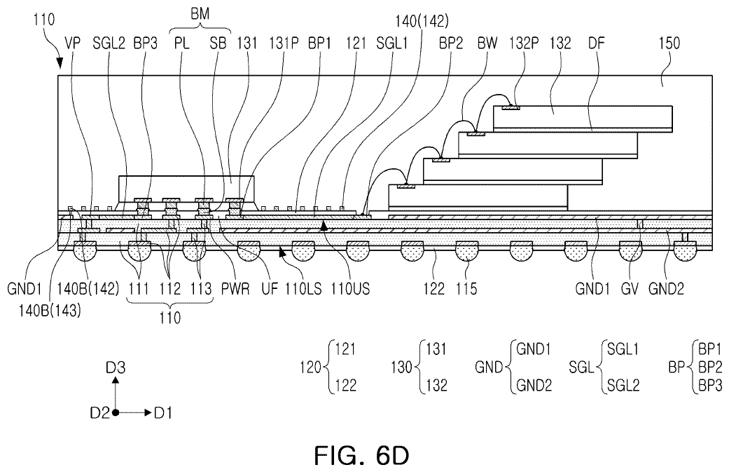

FIGS. 6A to 6D are drawings illustrating a method of manufacturing a semiconductor package, according to an example embodiment.

Referring to FIG. 6A, a preliminary substrate 110′ on which a protective layer 120 is formed may be prepared. The preliminary substrate 110′ may include a signal pattern SGL directly covered by an upper protective layer 121. The preliminary substrate 110′ may be a strip substrate on which unit substrates including the configurations illustrated in the drawings are connected. Subsequently, a first opening 121H1 and a second opening 121H2 penetrating the upper protective layer 121 may be formed. The first opening 121H1 may expose a via pad VP and/or a bonding pad BP such as, but not limited to a ground pattern GND, a signal pattern SGL, or the like. The signal pattern SGL may be adjacent to the ground pattern GND laterally and downwardly, and the signal pattern SGL and the ground pattern GND may be separated by an insulating layer 111. The second opening 121H2 may expose at least a part of the ground pattern GND. The second opening 121H2 may provide a connection area of the mesh pattern layer 140 in a subsequent process.

Referring to FIG. 6B, a mesh pattern layer 140 may be formed on the upper protective layer 121. The mesh pattern layer 140 may be formed by directly printing an EMI shielding material on the upper protective layer 121 using a printer 10. The mesh pattern layer 140 may include, but not be limited to, at least one of iron (Fe), nickel (Ni), gold (Au), silver (Ag), copper (Cu), or an alloy thereof. The mesh pattern layer 140 may be respectively formed on the first signal pattern SGL1 and the second signal pattern SGL2. Accordingly, since the signal pattern SGL is adjacent to the mesh pattern layer 140 upward, the propagation of electromagnetic waves generated when transmitting a high-frequency signal through the signal pattern SGL may be blocked, and electromagnetic interference generated inside the package may be prevented and/or reduced, when compared to a related semiconductor package.

The mesh pattern layer 140 may include first lines 141 and second lines 142 intersecting each other. The diameter of the mesh holes 140H may be determined in consideration of the wavelength of the electromagnetic waves emitted from the signal pattern SGL. The mesh pattern layer 140 may include a connecting via 143 formed within the second opening 121H2. The mesh pattern layer 140 may be connected to the ground pattern GND through a connecting via 143.

Referring to FIG. 6C, a first semiconductor chip 131 and a plurality of second semiconductor chips 132 may be mounted on a preliminary substrate 110′. The first semiconductor chip 131 may be flip-chip bonded on the preliminary substrate 110′. However, embodiments of the present disclosure are not limited thereto. The first semiconductor chip 131 may be connected to the interconnection layer 112 through a bonding bump BM. An underfill UF may surround the bonding bump BM between the first semiconductor chip 131 and the preliminary substrate 110′. The underfill UF may be formed by a capillary underfill (CUF) process. In some embodiments, the underfill UF may be formed by a molded underfill (MUF) process. However, embodiments of the present disclosure are not limited thereto.

A plurality of second semiconductor chips 132 may be wire bonded on a preliminary substrate 110′. The plurality of second semiconductor chips 132 may be connected to the interconnection layer 112 through bonding wires BW. The plurality of second semiconductor chips 132 may be stacked offset in at least one direction so that respective chip pads 132P are exposed. In some embodiments, the plurality of second semiconductor chips 132 may be stacked aligned in a vertical direction.

Referring to FIG. 6D, a molded layer 150 and external connection bumps 115 may be formed. The molded layer 150 may be formed by applying and curing EMC. The external connection bumps 115 may be formed by performing a reflow process after attaching solder balls. Thereafter, an electromagnetic shielding layer 155 may be formed on the surface of individual packages 100 separated by the sawing process (as shown in FIG. 4B). However, embodiments of the present disclosure are not limited thereto.

As set forth above, according to example embodiments, by introducing a mesh pattern layer on a high-speed transmission line, a semiconductor package preventing and/or reducing internal electromagnetic interference may be provided.

While example embodiments have been illustrated and described above, it is to be apparent to those skilled in the art that modifications and variations may be made without departing from the scope of the present disclosure as defined by the appended claims.

What is claimed is:

1. A semiconductor package, comprising:
a substrate comprising a plurality of signal patterns and a plurality of ground patterns;
an upper protective layer on an upper surface of the substrate and comprising a first opening exposing at least a first portion of each pattern of the plurality of signal patterns and the plurality of ground patterns and a second opening exposing at least a second portion of the plurality of ground patterns;
a first semiconductor chip on the upper protective layer and coupled with the plurality of signal patterns and the plurality of ground patterns through the first opening;
a plurality of second semiconductor chips around the first semiconductor chip and coupled with the plurality of signal patterns and the plurality of ground patterns through the first opening;
a mesh pattern layer on the upper protective layer, at least partially overlapping respective portions of the plurality of signal patterns and the plurality of ground patterns, and coupled with the plurality of ground patterns through the second opening;
a molded layer at least partially covering the first semiconductor chip, the plurality of second semiconductor chips, and the mesh pattern layer; and
a plurality of external connection bumps below the substrate.

2. The semiconductor package of claim 1, wherein the mesh pattern layer comprises:
a plurality of first lines;
a plurality of second lines intersecting the plurality of first lines; and
a plurality of mesh holes defined by the plurality of first lines and the plurality of second lines.

3. The semiconductor package of claim 2, wherein each hole of the plurality of mesh holes have at least one of a circular planar shape or a polygonal planar shape.

4. The semiconductor package of claim 2, wherein a maximum width of each mesh hole of the plurality of mesh holes is less than or equal to 5% of a wavelength of an electromagnetic wave generated from the plurality of signal patterns.

5. The semiconductor package of claim 2, wherein at least one line from among the plurality of first lines and the plurality of second lines at least partially overlaps the second opening, and
wherein the mesh pattern layer further comprises a connecting via within the second opening and coupling the at least one line with the plurality of ground patterns.

6. The semiconductor package of claim 5, wherein the second opening comprises a trench shape extending along a length direction of the at least one line.

7. The semiconductor package of claim 5, wherein a first line width of the at least one line is greater than line widths of remaining lines the plurality of first lines and the plurality of second lines except the at least one line.

8. The semiconductor package of claim 1, wherein the plurality of ground patterns comprise a first ground pattern adjacent to side surfaces of the plurality of signal patterns, and a second ground pattern adjacent to lower surfaces of the plurality of signal patterns, and
wherein the plurality of signal patterns at least partially overlap the first ground pattern in a horizontal direction, and at least partially overlap the mesh pattern layer and the second ground pattern in a vertical direction.

9. The semiconductor package of claim 8, wherein the substrate further comprises a ground via coupling the first ground pattern with the second ground pattern.

10. The semiconductor package of claim 1, wherein the plurality of signal patterns comprise a first signal pattern coupling the first semiconductor chip with the plurality of second semiconductor chips, and a second signal pattern coupling the first semiconductor chip with the plurality of external connection bumps, and
wherein the first signal pattern and the second signal pattern extend on the upper surface of the substrate.

11. The semiconductor package of claim 10, wherein the mesh pattern layer comprises a first mesh pattern layer at least partially overlapping the first signal pattern, and a second mesh pattern layer at least partially overlapping the second signal pattern.

12. The semiconductor package of claim 11, wherein the mesh pattern layer further comprises a third mesh pattern layer coupling the first mesh pattern layer with the second mesh pattern layer.

13. The semiconductor package of claim 1, wherein the plurality of signal patterns and the plurality of ground patterns comprise a bonding pad portion exposed through the first opening,
wherein the first semiconductor chip is coupled with the bonding pad portion through a bonding bump, and
wherein the plurality of second semiconductor chips are coupled with the bonding pad portion through a bonding wire.

14. The semiconductor package of claim 1, further comprising:
an electromagnetic shielding layer extending along a surface of the molded layer and coupled with the plurality of ground patterns on at least one side of the substrate.

15. The semiconductor package of claim 14, wherein the electromagnetic shielding layer and the mesh pattern layer comprise at least one of iron (Fe), nickel (Ni), gold (Au), silver (Ag), copper (Cu), or an alloy thereof.

16. The semiconductor package of claim 1, wherein the substrate further comprises a plurality of power patterns,
wherein the first semiconductor chip and the plurality of second semiconductor chips are coupled to the plurality of power patterns,
wherein the plurality of signal patterns comprise a first group of one or more first signal patterns and a second group of one or more second signal patterns spaced apart with the plurality of power patterns therebetween, and
wherein the mesh pattern layer comprises a first mesh pattern layer at least partially overlapping one or more signal patterns of the first group and a second mesh pattern layer at least partially overlapping signal one or more patterns of the second group.

17. The semiconductor package of claim 16, wherein the first mesh pattern layer and the second mesh pattern layer are spaced apart from each other and are respectively coupled with the plurality of ground patterns.

18. A semiconductor package, comprising:
a substrate comprising a signal pattern and a ground pattern adjacent to a side surface of the signal pattern and a lower surface of the signal pattern;
an upper protective layer at least partially covering respective portions of the signal pattern and the ground pattern;
a controller and one or more memory chips on the upper protective layer and coupled with the signal pattern and the ground pattern;
a mesh pattern layer on the upper protective layer adjacent to an upper surface of the signal pattern and comprising a plurality of holes at least partially overlapping the signal pattern;
a molded layer at least partially covering the controller, the one or more memory chips, and the mesh pattern layer; and
an electromagnetic shielding layer at least partially covering respective surfaces of the substrate and the molded layer,
wherein the mesh pattern layer is coupled with the electromagnetic shielding layer through the ground pattern.

19. A semiconductor package, comprising:
a substrate comprising a first bonding pad, a second bonding pad, and a first signal pattern coupling the first bonding pad with the second bonding pad;
an upper protective layer on the substrate and at least partially covering the first signal pattern;
a first semiconductor chip on the upper protective layer and comprising a plurality of first chip pads coupled with the first bonding pad;
a plurality of second semiconductor chips on the upper protective layer and comprising a plurality of second chip pads coupled with the second bonding pad; and
a first mesh pattern layer on the upper protective layer between the first bonding pad and the second bonding pad and comprising a first plurality of holes at least partially overlapping the first signal pattern.

20. The semiconductor package of claim 19, wherein the substrate further comprises a third bonding pad, a via pad coupled with an external connection bump, and a second signal pattern coupling the third bonding pad with the via pad,
wherein at least one of the plurality of first chip pads is coupled with the third bonding pad, and
wherein the semiconductor package further comprises a second mesh pattern layer on the upper protective layer and comprising a second plurality of holes at least partially overlapping the second signal pattern between the third bonding pad and the via pad.
